(19) United States
(12) Patent Application Publication
(10) Pub. No.: US 2009/0258497 A1
(43) Pub. Date: Oct. 15, 2009

(54) PHOTORESIST RESIN, AND METHOD FOR FORMING PATTERN AND METHOD FOR MANUFACTURING DISPLAY PANEL USING THE SAME

(75) Inventors: Jeong-Min Park, Seoul (KR); Doo-Hee Jung, Seoul (KR); Jung-Soo Lee, Seoul (KR); Hi-Kuk Lee, Yongin-si (KR); Sae-Tae Oh, Pyungtaek-si (KR); Jae-Young Choi, Suwon-si (KR); Doek-Man Kang, Seongnam-si (KR)

Correspondence Address: CANTOR COLBURN, LLP, 20 Church Street, 22nd Floor, Hartford, CT, 06103, US

(73) Assignees: SAMSUNG ELECTRONICS CO., LTD., Suwon-si (KR); AZ ELECTRONICS MATERIALS (JAPAN) K.K., Tokyo (JP)

(21) Appl. No.: 12/389,296

(22) Filed: Feb. 19, 2009

(30) Foreign Application Priority Data
Apr. 15, 2008 (KR) 10-2008-0034877

(51) Int. Cl. H01L 21/311; G03F 7/00

(52) U.S. Cl. 438/694; 430/270.1; 430/281.1; 430/323; 257/E21.257

(57) ABSTRACT

A photoresist resin composition, a method for forming a pattern and a method for manufacturing a display panel using the photoresist resin composition are disclosed. The photoresist resin composition includes an alkali soluble resin, a photoresist compound, and a solvent, wherein the alkali soluble resin includes a first polymer resin represented by the following Chemical Formula 1, wherein, of R₁, R₂, R₃, R₄, R₅ and R₆, at least one is a hydroxyl group, at least two are methyl groups and any remaining groups are hydrogen, and of R₇, R₈, R₉, R₁₀ and R₁₁, at least one is a hydroxyl group, at least two are methyl groups and any remaining groups are hydrogen.

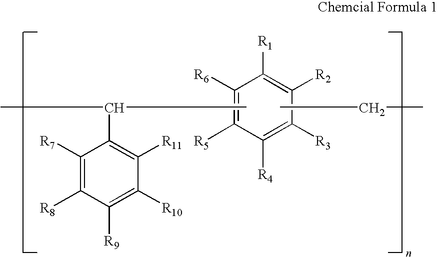

This application claims priority to Korean Patent Application No. 10-2008-0034877, filed Apr. 15, 2008, and all the benefits accruing therefrom under 35 U.S.C. 119, the contents of which are incorporated herein by reference in their entirety.

### BACKGROUND OF THE INVENTION

(a) Field of the Invention

The present invention relates to a photoresist resin, and a method for forming patterns and a method for manufacturing a display panel using the photoresist resin.

(b) Description of the Related Art

Display devices such as a liquid crystal display (“LCD”) or an organic light emitting diode (“OLED”) display are typically formed from a plurality of thin films such as for example a plurality of conductive layers, a semiconductor layer, an insulating layer for insulating the conductive and semiconductor layers, and other such layers.

Thin film transistor array panels also include a plurality of thin films such as a gate conductive layer, a semiconductor layer, and a data conductive layer, and these thin films may be patterned by photolithography using masks. Photolithography, as used herein, refers to a method of forming a pattern in which a photoresist film comprising a photoresist resin is coated in a thin film on the substrate to be patterned, exposed, and developed to form a photoresist pattern of a certain shape, which is then used to etch the thin film.

As the number of masks increases, additional exposing, developing and etching processes are performed, increasing fabrication cost and manufacturing time.

Therefore, a method has been proposed for reducing the number of masks by forming the semiconductor layer and the data conductive layer by using a single mask. In this method, the semiconductor layer and the data conductive layer are stacked sequentially, a photoresist film is coated on a surface thereof, and the portion of the photoresist film on the semiconductor layer where a channel is to be formed is exposed to make the thicknesses different.

For the photoresist film, sensitivity and contrast are important features.

Sensitivity of a photoresist is a measure of how sensitive the photoresist film is to light when exposed. If the photoresist film has high sensitivity, a photoresist pattern can be formed in the photoresist film with a lower dose of light, and so a photoresist film with high sensitivity is advantageous in terms of productivity. Contrast of a photoresist is a measure of the difference between the solubility of an exposed portion of the photoresist film and that of a non-exposed portion. A photoresist film having a high contrast is advantageous for forming a well-defined pattern, and in particular, it is advantageous for forming a fine pattern. In addition, in order to form such a fine pattern, heat resistance in the photoresist film is necessary.

However, photoresist films having high sensitivity and high contrast may change in thickness with even a small change in light exposure, and thus for an exposed portion of the photoresist film, achieving uniform thickness is difficult.

### BRIEF SUMMARY OF THE INVENTION

In an embodiment, a photoresist resin composition comprises a photoresist resin including an alkali soluble resin and a photoresist compound; and a solvent, wherein the alkali soluble resin includes a first polymer resin represented by the following Chemical Formula 1.

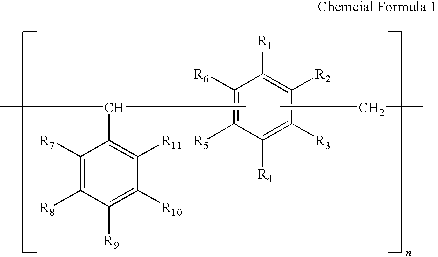

In the above Chemical Formula 1, wherein, among R₁, R₂, R₃, R₄, R₅ and R₆, at least one is a hydroxyl group, at least two are methyl groups and any remaining groups are hydrogen, and among R₇, R₈, R₉, R₁₀ and R₁₁, at least one is a hydroxyl group, at least two are methyl groups and any remaining groups are hydrogen.

The alkali soluble resin may further include a second polymer resin selected from the group consisting of a novolak resin, an acrylic resin, and combinations thereof.

The first polymer resin may be present in an amount of about 5 wt % to about 50 wt % based on the total weight of the alkali soluble resin.

The first polymer resin may be formed from a phenol monomer and an aldehyde compound, and the aldehyde compound may be a salicylic aldehyde compound.

The photoresist compound may be a diazonaphthoquinone compound.

The photoresist resin composition may include about 5 wt % to about 30 wt % of an alkali soluble resin, about 2 wt % to about 10 wt % of a photoresist compound, and the remaining amount of a solvent, based on the total weight of the photoresist resin composition.

In another embodiment, a method for forming a pattern includes: forming a thin film on a surface of a substrate; coating a photoresist film from a photoresist resin composition including an alkali soluble resin including a first polymer resin represented by the above Chemical Formula 1, a photoresist compound, and a solvent, on a surface of the thin film opposite the substrate; exposing and developing the photoresist film to form a photoresist pattern; and etching the portions of the thin film not masked by the photoresist pattern.

The alkali soluble resin may further include a second polymer resin selected from the group consisting of a novolak resin, an acrylic resin, and combinations thereof.

The first polymer resin may be included in an amount of about 5 wt % to about 50 wt % based on the total weight of the alkali soluble resin.

In another embodiment, a method for manufacturing a display panel includes: forming a gate line; sequentially forming a gate insulating layer, a semiconductor layer, and a data conductive layer on the gate line; coating a photoresist film; forming a photoresist film on a surface of the data conductive layer comprising coating a photoresist resin composition including an alkali soluble resin including a first polymer resin represented by the above Chemical Formula 1, a photoresist compound, and a solvent on the data conductive layer; exposing and developing the photoresist film to form a photoresist pattern; first etching the data conductive layer and the semiconductor layer by using the photoresist pattern; removing a portion of the photoresist pattern and leaving a portion of the photoresist pattern; and secondly etching the data conductive layer by using the remaining portion of the photoresist pattern to form source and drain electrodes.

The alkali soluble resin may further include a second polymer resin selected from the group consisting of a novolak resin, an acrylic resin, and a combination thereof.

The first polymer resin may be included in an amount of about 5 wt % to about 50 wt % based on the total weight of the alkali soluble resin.

The forming of the photoresist pattern may include irradiating the photoresist film with a light exposure energy of about 20 mJ/cm² to about 40 mJ/cm².

The forming of the photoresist pattern may include performing thermal treatment, and the thermal treatment may be performed at about 120° C. to about 140° C.

The photoresist pattern may include a first portion and a second portion thinner than the first portion, wherein when the photoresist pattern is partially removed, the second portion may be removed.

The second portion of the photoresist pattern may be positioned between the source and drain electrodes.

In another embodiment, a photoresist film comprises an alkali soluble resin represented by Chemical Formula 1 and a photoresist compound, wherein a pattern formed from the photoresist film shows no thermal deformation at a temperature of greater than about 120° C.

### BRIEF DESCRIPTION OF THE DRAWINGS

FIG. 1 is a layout view of an exemplary thin film transistor (“TFT”) array panel according to an embodiment.

FIG. 2 is a sectional view taken along line II-II′ of the TFT array panel in FIG. 1.

FIGS. 3, 4, 5, 6, 7, 8, 9, and 10 are each sequential cross-sectional views showing an exemplary method for manufacturing the TFT array panel in FIGS. 1 and 2.

FIGS. 11A, 11B, 12A, 12B, 13A, 13B, 14A, and 14B are scanning electron micrograph (SEM) images comparatively showing a pattern shape of an exemplary photoresist resin according to an embodiment (11A, 12A, 13A, and 14A) and that of a comparative example (11B, 12B, 13B, and 14B).

FIG. 15 is a graph showing light exposure required for forming a critical dimension (“CD”) (or ultra-fine line width) of a desired shape for an exemplary photoresist resin according to an (A) and for that of the comparative example (B).

### DETAILED DESCRIPTION OF THE INVENTION

A photoresist resin according to an exemplary embodiment will now be described.

In the drawings, the thickness of layers, films, panels, regions, and the like, are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, and the like may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, first element, component, region, layer or section discussed below could be termed second element, component, region, layer or section without departing from the teachings of the present invention.

As used herein, the singular forms “a,” “an” and “the” are intended to comprise the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The photoresist resin composition according to an embodiment includes a photoresist resin comprising an alkali soluble resin and a sensitizer (photoresist compound), and a solvent.

The alkali soluble resin includes a novolak resin represented by the following Chemical Formula 1.

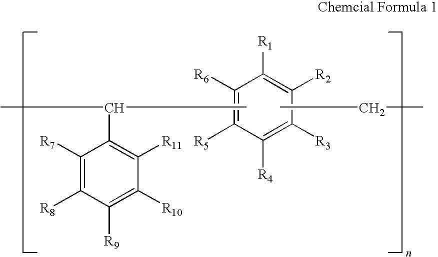

Among R₁, R₂, R₃, R₄, R₅ and R₆, at least one is a hydroxyl group, at least two are methyl groups and any remaining groups are hydrogen, and, among R₇, R₈, R₉, R₁₀ and R₁₁, at least one is a hydroxyl group, at least two are methyl groups any remaining groups are hydrogen, and ‘n’ is about 5 to about 10,000.

The novolak resin is a polymer obtained by reacting a phenol monomer and an aldehyde compound in the presence of an acid catalyst.

Here, as the phenol monomer, dimethyl phenol, in which two methyl groups CH₃ are bonded to an aromatic ring, such as for example xylenol, or a trimethyl phenol, in which three methyl groups CH₃ are bonded to the aromatic ring, may be used.

As the aldehyde compound, in an exemplary embodiment, salicylaldehyde may be used.

The acid catalyst added in making the phenol compound and the aldehyde compound react may be selected from the group consisting of hydrochloric acid, nitric acid, sulfuric acid, formic acid, and oxalic acid.

The novolak resin in Chemical Formula 1 may be included in an amount of about 1 wt % to about 100 wt % based on the total weight of the alkali soluble resin, specifically in an amount of about 1 wt % to about 50 wt %. As the alkali soluble resin, the novolak resin of Chemical Formula 1 may thus be used alone, or may be included as a first novolak resin in combination with an additional resin including at least one a second novolak resin not identical with the novolak resin of Chemical Formula 1, an acrylic resin, or a combination thereof.

The second novolak resin may be synthesized by using a different phenol monomer and/or aldehyde compound from that used for the above-described first novolak resin.

The phenol monomer may m-cresol and p-cresol in a particular ratio, and as the aldehyde compound, one or more selected from the group consisting of formaldehyde, p-formaldehyde, benzaldehyde, nitrobenzaldehyde, acetaldehyde, combinations thereof, and the like may be used alone or as a mixture.

The acrylic resin may include one or more acrylic resins selected from the group consisting of 1,3-butylene glycol diacrylate, 1,4-butane diol diacrylate, ethylene glycol diacrylate, triethylene glycol diacrylate, polyethylene glycol diacrylate, pentaerythritol tetra(meth)acrylate, dipentaerythritol diacrylate, dipentaerythritol polyacrylate, sorbitol triacrylate, bisphenol A diacrylate and derivatives thereof, trimethylolpropane triacrylate, methacrylate pentaerythritol tetra acrylate, dipentaerythritol pentaacrylate, dipentaerythritol pentamethacrylate, dipentaerythritol hexaacrylate, dipentaerythritol hexamethacrylate, and combinations thereof.

In an embodiment, the additional resin may be included in an amount of 0 wt % to about 99 wt % based on the total weight of the alkali soluble resin, specifically about 50 wt % to about 99 wt %.

In an embodiment, the photoresist resin composition comprises the alkali soluble resin in an amount of about 5 wt % to about 30 wt %, based on the total weight of the photoresist resin composition.

The photoresist compound reacts when exposed to light by a photo chemical reaction to generate acid or radical, and may be selected from the group consisting of for example, diazide compounds, benzophenol compounds, triazine compounds, sulfonium compounds, azo compounds including diazonaphthoquinones, and derivatives thereof. Among these, a diazonaphthoquinone compound is preferred.

The photoresist compound may be included in an amount of about 0.1 wt % to about 10 wt % based on the total weight of the photoresist resin composition. Where the photoresist compound is used in an amount less than about 0.1 wt %, the response speed (i.e., photospeed) of a photoresist film prepared therefrom would degrade excessively and be too slow for practical manufacturing applications, whereas if the photoresist compound is included in an amount of greater than 10 wt %, the response speed (i.e., photospeed) of the photoresist film prepared from the photoresist resin composition would be too sharply increased to form a desired profile.

The alkali soluble resin and the photoresist compound are dissolved in an organic solvent to form the photoresist resin composition. The organic solvent may be selected from the group consisting of, for example, ethyl acetate, butyl acetate, diethylene glycol dimethyl ether, diethylene glycol dimethyl ethyl ether, methyl methoxy propionate, ethyl ethoxy propionate, ethyl lactate, propylene glycol methyl ether acetate, propylene glycol methyl ether, propylene glycol propyl ether, methyl cellosolve acetate, ethyl cellosolve acetate, diethylene glycol methyl acetate, diethylene glycol ethyl acetate, acetone, methyl isobutyl ketone, cyclohexanone, dimethyl formamide, N,N-dimethyl acetamide, N-methyl-2-pyrolidone, [symbol] -butyrolactone, diethyl ether, ethylene glycol dimethyl ether, diglyme, tetrahydrofuran, methanol, ethanol, propanol, isopropanol, methyl cellosolve, ethyl cellosolve, diethylene glycol methyl ether, diethylene glycol ethyl ether, dipropylene glycol methyl ether, toluene, xylene, hexane, heptane, octane, combinations thereof, and the like.

The solvent may comprise the balance of the photoresist resin composition excluding the weight of the above-mentioned components (alkali soluble resin and photosensitive compound) from the total weight of the photoresist resin composition, and specifically, may be included in an amount of about 60 wt % to about 97 wt %, specifically about 60 wt % to about 90 wt %.

In addition to the above components, the photoresist resin composition may contain a small amount of an additive such as a cross-linking agent for forming a cross-linking bond, a plasticizer, a stabilizer, a surfactant, a combination thereof, or the like.

Also in an embodiment, a photoresist film comprises the alkali soluble resin comprising a polymer resin represented by Chemical Formula 1 and the photoresist compound, wherein a pattern formed from the photoresist film shows no thermal deformation at a temperature of greater than about 120° C., specifically greater than or equal to about 130° C.

An example of the use of the photoresist resin fabricated according to an embodiment will be described as follows. As one skilled in the art will appreciate, the described embodiments may be modified in various different ways, all without departing from the spirit or scope of the present invention.

### Exemplary Embodiment 1

Preparation of a Photoresist Composition

Xylenol and salicylaldehyde were polycondensed in the presence of oxalic acid catalyst to provide the salicylaldehyde novolak resin of Chemical Formula 1. In addition, a cresol monomer in which m-cresol and p-cresol were mixed in the ratio of about 60:40 and formaldehyde were polycondensed in the presence of oxalic acid catalyst to manufacture a cresol novolak resin having a weight average molecular weight (Mw) of about 8,000 g/mol.

Next, about 15 parts by weight of the salicylaldehyde novolak resin, about 8 parts by weight of the cresol novolak resin, and about 5 parts by weight of diazonaphthoquinone sulfonic acid trihydroxybenzophenone ester as a photoresist compound were dissolved in about 85 parts by weight of propylene glycol methyl ether acetate (“PGMEA”) and then filtered through a filter with a pore size of about 0.2 μm to manufacture a photoresist resin composition.

Photolithography

The photoresist resin was spin-coated on a glass substrate to form a photoresist film. A mask was disposed on the photoresist film, and the photoresist film was then exposed through the mask. Thereafter, the exposed portion of the photoresist film was developed with a developer of 2.38 wt % of tetramethyl ammonium hydroxide (“TMAH”) and hard-baked to form a photoresist pattern. The shape of the photoresist pattern was observed by scanning electron microscopy (SEM).

### Exemplary Embodiment 2

Xylenol and salicylaldehyde were polycondensed in the presence of oxalic acid catalyst to provide the salicylaldehyde novolak resin of Chemical Formula 1. In addition, a cresol monomer in which m-cresol and p-cresol were mixed in the ratio of about 60:40 and formaldehyde were polycondensed in the presence of oxalic acid catalyst to provide a cresol novolak resin having a weight average molecular weight of about 8,000 g/mol.

About 30 parts by weight of the salicylaldehyde novolak resin, about 5 parts by weight of the cresol novolak resin, and about 5 parts by weight of diazonaphthoquinone sulfonic acid trihydroxybenzophenone ester as a photoresist compound were dissolved in about 85 parts by weight of propylene glycol methyl ether acetate (PGMEA) and then filtered through a filter having a pore size of about 0.2 μm to provide a photoresist resin composition.

The photoresist resin composition was subject to photolithography in the same manner as in the Exemplary Embodiment 1 to form a pattern. The shape of the photoresist pattern was observed by SEM.

### Comparative Example

A cresol monomer in which m-cresol and p-cresol were mixed in a ratio of about 60:40 and formaldehyde were polycondensed in the presence of an oxalic acid catalyst to manufacture a cresol novolak resin having a weight average molecular weight of about 8,000 g/mol.

About 10 parts by weight of cresol novolak resin and about 5 parts by weight of diazonaphthoquinone sulfonic acid trihydroxybenzophenone ester as a photoresist compound were dissolved in about 85 parts by weight of propylene glycol methyl ether acetate (PGMEA) and then filtered through a filter having a pore size of about 0.2 μm to provide a comparative photoresist resin composition.

The comparative photoresist resin was subject to photolithography in the same manner as in Exemplary Embodiment 1 to form a pattern. The shape of the photoresist pattern was observed by SEM.

Evaluation

Heat Resistance

TABLE 1

| | 120° C. | 125° C. | 130° C. | 135° C. | 140° C. |
|---|---|---|---|---|---|
| Exemplary | ◯ | ◯ | ◯ | Δ | X |
| Embodiment 1 | | | | | |
| Exemplary | ◯ | ◯ | ◯ | ◯ | ◯ |
| Embodiment 2 | | | | | |
| Comparative | X | X | X | X | X |
| Example | | | | | |

* ◯: No thermal deformation/ Δ: A little thermal deformation/ X: Thermally deformed

With reference to Table 1, the pattern formed using the photoresist resin composition according to the Exemplary Embodiment 1 exhibits heat resistance of up to 130° C., while that according to the Exemplary Embodiment 2 exhibits heat resistance of up to above 140° C. In Exemplary Embodiment 2, it can be seen that the photoresist resin has a greater heat resistance. Without wishing to be bound by theory, this is believed to be achieved by the increase in the content of the salicylaldehyde novolak. Meanwhile, a comparative photoresist resin according to a comparative example that does not have the salicylaldehyde novolak resin shows thermal deformation even as low as 120° C., which is evidence of low heat resistance as a result of the lack of the salicylaldehyde novolak resin.

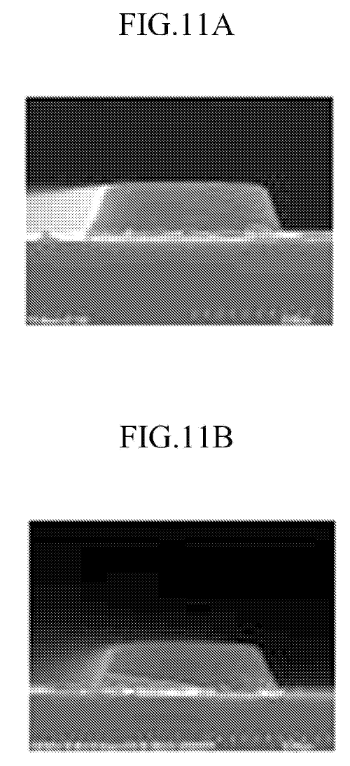

The heat resistance of the photoresist resins according to the Exemplary Embodiment 2 and the comparative example will now be described with reference to FIGS. 11A to 14B.

FIGS. 11A to 14B are SEM micrographs comparatively showing the pattern shape of a photoresist resin according to the exemplary embodiment 2 and that of the comparative example.

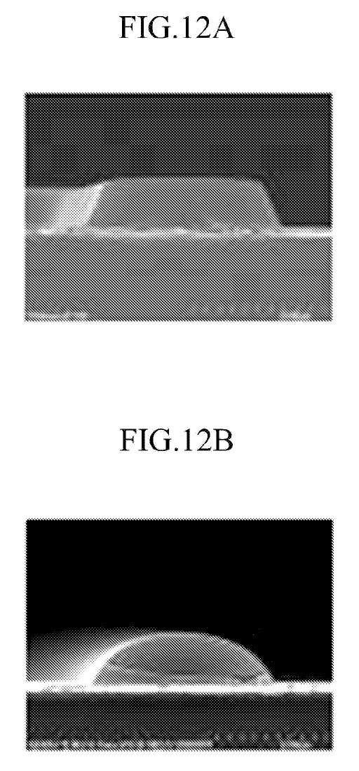

Specifically, FIGS. 11A and 11B are SEM micrographs showing pattern shapes before thermal treatment of a pattern prepared using the photoresist resin according to Exemplary Embodiment 2 and that of the Comparative Example. FIGS. 12A, 13A, and 14A are SEM micrographs showing the shapes of patterns obtained by thermally treating the photoresist resin according to Exemplary Embodiment 2 at about 120° C., at about 130° C., and about 140° C., respectively. FIGS. 12B, 13B, and 14B are SEM micrographs showing the shapes of patterns obtained by thermally treating the photoresist resin according to the Comparative Example at about 120° C., at about 130° C., and about 140° C., respectively.

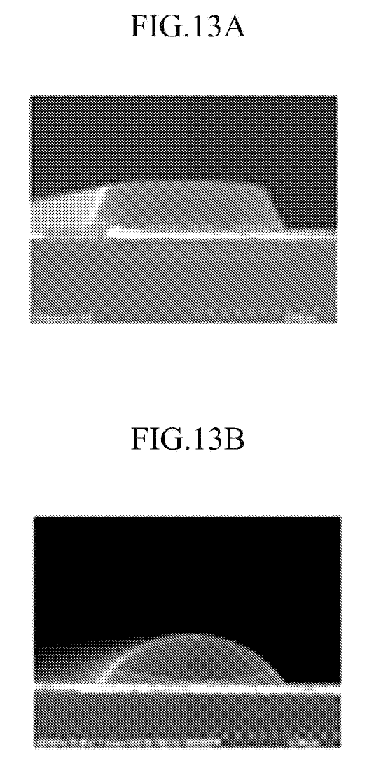

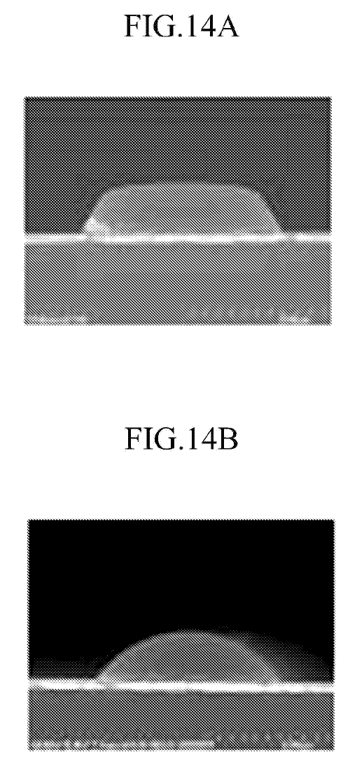

As shown in the drawings, the pattern prepared from the photoresist resin according to the Exemplary Embodiment 2 has a pattern profile that has been little deformed even at about 120° C. (FIG. 12A), at about 130° C. (FIG. 13A), and at about 140° C. (FIG. 14A) when compared to the pattern profile before thermal treatment (FIG. 11A), while, it is noted that, the pattern prepared from the comparative photoresist resin according to the Comparative Example has a profile of an initial pattern that exhibits deformation as low as about 120° C.

Sensitivity

TABLE 2

| | Light Exposure (mJ/cm²) |
|---|---|
| Exemplary Embodiment 1 | 33 |
| Exemplary Embodiment 2 | 20 |
| Comparative Example | 40 |

In Table 2, it can be seen that photoresist resins reacts more sensitively with increasing salicylaldehyde novolak content, wherein the light exposure dose decreases, which means that the photoresist resin has higher sensitivity. It was ascertained that Exemplary Embodiments 1 and 2 have a higher sensitivity to that of the Comparative Example, and in particular, it is noted that Exemplary Embodiment 2 shows the sensitivity higher by about 1.6 times or more by increasing the content of the salicylaldehyde novolak resin when compared with Exemplary Embodiment 1.

Film Thickness Deviation

TABLE 3

| | Film Thickness Deviation (Å) |
|---|---|
| Exemplary Embodiment 1 | 1400 |
| Exemplary Embodiment 2 | 1500 |
| Comparative Example | 1600 |

Table 3 shows thickness deviations of partially exposed regions when a slit mask was used. As shown in Table 3, it is noted that Exemplary Embodiments 1 and 2 have smaller film thickness deviations compared to that of the Comparative Example. In general, if a photoresist film has high sensitivity, the thickness of a residual photoresist film changes significantly even with a slight change in light exposure, so the thickness deviation is high, but comparatively, it is noted that the photoresist film according to the exemplary embodiments 1 and 2 have a smaller film thickness deviation than the comparative example even although the comparative example exhibits a relatively high sensitivity.

### Exemplary Embodiment 3

The photoresist resin compositions according to Exemplary Embodiment 2 and the Comparative Example were each applied to a thin film transistor (TFT) array panel, and the heat resistance, sensitivity, and film thickness uniformity of the resulting photoresist films were measured after development of the pattern. The TFT array panel was manufactured according to a method in an Exemplary Embodiment 4 to be described.

As in the above-described evaluation for heat resistance, the TFT array panel according to the present exemplary embodiment showed that its pattern profile was not deformed even at above about 140° C., while the pattern comprising the comparative photoresist resin according to the comparative example was thermally deformed at below about 120° C., deforming its profile.

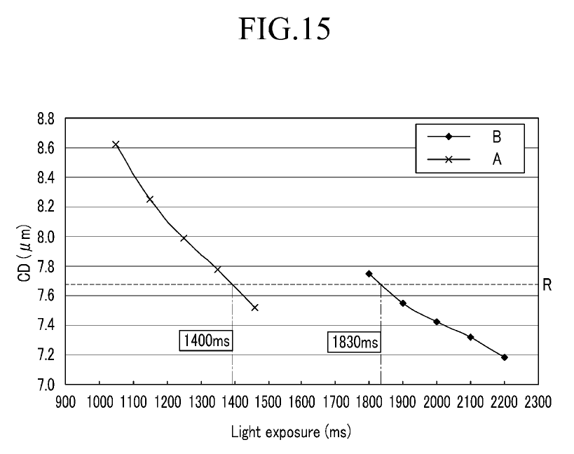

The sensitivity will be described with reference to FIG. 15.

FIG. 15 is a graph showing light exposure required for forming a critical dimension (CD) (or ultra-fine line width) of a desired shape in the case of using the photoresist resin according to the embodiment of the present invention and that of the Comparative Example.

With reference to FIG. 15, when the ultra-fine line width of about 7.7 μm is formed, it is noted that the pattern prepared from photoresist resin (A) according to the present exemplary embodiment 2 requires light exposure of about 1400 ms, while the pattern prepared from the comparative photoresist resin (B) according to the Comparative Example requires light exposure of about 1830 ms. It will be noted that all exposures are conducted using a light source of the same intensity, operating at a wavelength of 436 nm and 405 nm.

Thus, compared with the photoresist resin according to the Comparative Example, the photoresist resin according to the exemplary embodiment 2 can allow the formation of a desired ultra-fine line width, which means that it has a higher sensitivity.

Finally, as for the film thickness uniformity, a photoresist pattern was formed on the array panel including a plurality of TFTs by using a mask, the thickness of a partially exposed portion of the photoresist film was measured, and then, their thickness deviation was calculated. The partially exposed region corresponds to positions where each TFT channel is to be formed. A maximum thickness and a minimum thickness of the partially exposed portion of the photoresist film on the entire array panel were checked and their difference was used as a thickness deviation. This was repeatedly performed a total of twelve times to obtain an average value.

The results show that when the photoresist resin according to the present exemplary embodiment 2 was used, a thickness deviation of the partially exposed portion of the photoresist film at the plurality of TFTs formed on the array panel was 3034 Å. Meanwhile, when the comparative photoresist resin according to the Comparative Example was used, a thickness deviation of the partially exposed portion of the photoresist film was 4529 Å.

Thus, it can be seen that the use of the photoresist resin according to the present exemplary embodiment 2 results in the partially exposed portion of the photoresist film have less thickness deviation, and thus, it can be considered that the thickness uniformity of the photoresist film according to the present exemplary embodiment 2 is superior to that of the Comparative Example.

### Exemplary Embodiment 4

In the following detailed description, only certain exemplary embodiments will be shown and described, simply by way of illustration such that an ordinary person in the art to which the present invention pertains can easily implement the thin film transistor formed by using the photoresist resin as described above. As those skilled in the art would realize, the described embodiments may be modified in various different ways, all without departing from the spirit or scope of the present invention.

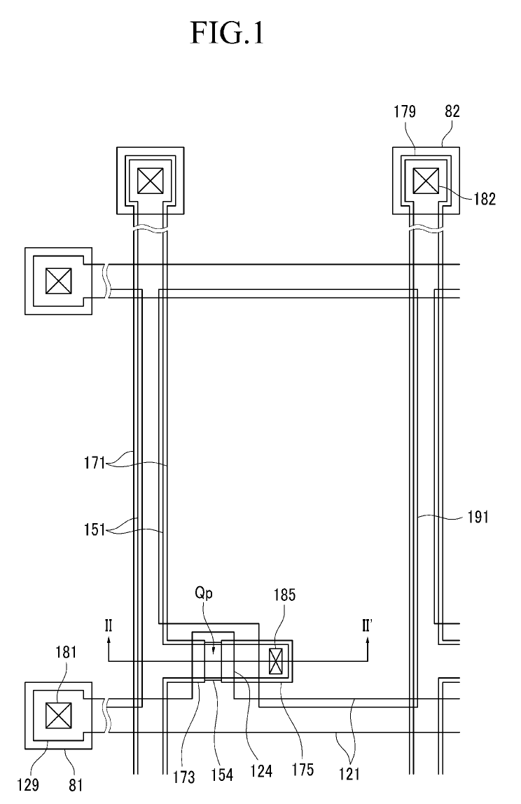

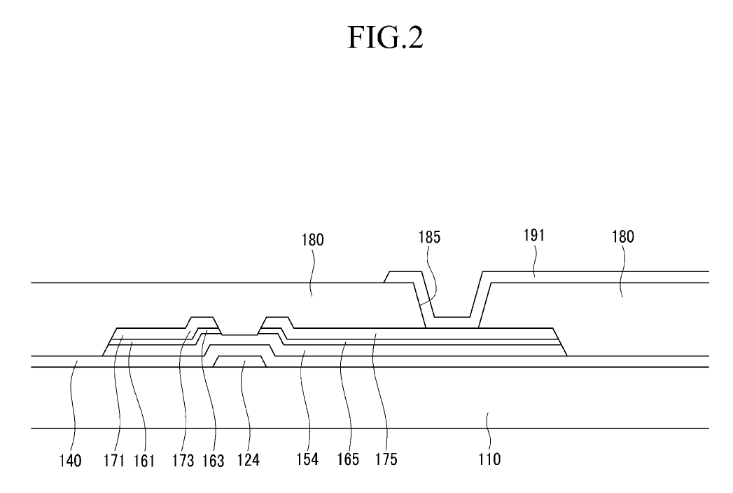

First, a TFT array panel according to an exemplary embodiment of the present invention will now be described with reference to FIGS. 1 and 2.

FIG. 1 is a layout view of a thin film transistor (TFT) array panel according to an embodiment, and FIG. 2 is a sectional view taken along line II-II′ of the TFT array panel in FIG. 1.

A plurality of gate lines 121 transferring gate signals is formed on a surface of an insulation substrate 110. Each gate line 121 includes a gate electrode 124 extending upwardly (i.e., perpendicular to the plane of the insulation substrate 110) and an end portion 129 that is larger that the gate line 121 for connection with an external circuit.

A gate insulating layer 140 made of silicon nitride (SiNx) or the like is formed on the surface of the insulation substrate 110 having gate lines 121, and semiconductor stripes 151 made of amorphous or crystalline silicon are formed on a surface of gate insulating layer 140 to extend in a vertical direction from the gate insulating layer 140. It will be appreciated that, where used herein, “vertical direction” describes the direction perpendicular to the plane of the substrate, along the direction of successive application of features. The semiconductor stripes 151 include projections 154 extending toward the gate electrodes 124.

A plurality of ohmic contact stripes 161 and a plurality of ohmic contact islands 165, which are made of a material such as silicide or n+ hydrogenated amorphous silicon in which an n-type impurity is doped therein with high density, are formed on the surface of the gate insulating layer 140 having the semiconductor stripes 151. The ohmic contact stripes 161 include projections 163 extending toward the projections 154 of the semiconductor stripes 151, and the projections 163 of the ohmic contact stripes 161 and the ohmic contact islands 165 are positioned as a pair on the projections 154 of the semiconductor stripes 151.

A plurality of data lines 171 and a plurality of data electrodes 175 are formed on a surface of the gate insulating layer 140 having the ohmic contact stripes 161 (as seen in cross-section in FIG. 2; not shown in FIG. 1) and the ohmic contact islands 165 (as seen in cross-section in FIG. 2; not shown in FIG. 1).

The data lines 171 extend in a vertical direction to cross the gate lines 121 and transfer data voltages. A plurality of branches extending toward the drain electrodes 175 from the data lines 171 form source electrodes 173, and a pair of a source electrodes 173 and a drain electrode 175 face each other on the gate electrode 124.

The gate electrode 124, the source electrode 173, and the drain electrode 175 form a TFT together with the projected semiconductor 154, and a channel of the TFT is formed at the projection 154 of the semiconductor stripe 151 between the source electrode 173 and the drain electrode 175.

The semiconductor stripes 151 have substantially the same planar shape as the data lines 171 and the drain electrodes 175, except for the shape of the channel region (Qp) between the source electrode 173 and the drain electrode 175.

The ohmic contact stripes 161 are interposed between surfaces of the semiconductor stripes 151 and the data lines 171, and have the substantially same planar shape as the data lines 171. The ohmic contact islands 165 are interposed between surfaces the semiconductor stripes 151 and the drain electrodes 175, and have the substantially same planar shape as the drain electrodes 175.

A passivation layer 180 is formed on the surface of the gate insulating layer 140 having the data lines 171 and the drain electrodes 175. The passivation layer 180 includes contact holes 185 and 182 exposing the drain electrodes 175 and end portions 179 of the data lines 171. The passivation layer 180 and the gate insulating layer 140 have contact holes 181 exposing the end portions 129 of the gate lines 121.

A pixel electrode 191 and contact assistants 81 and 82 are formed on a surface of the passivation layer 180 opposite the gate insulating layer 140.

The pixel electrode 191 is electrically connected with the drain electrode 175 via the contact hole 185, and receives a data voltage from the drain electrode 175.

The contact assistants 81 and 82 are connected with the end portion 129 of the gate line 121 and the end portion 179 of the data line 171 via the contact holes 181 and 182, respectively. The contact assistants 81 and 82 complement bonding characteristics of the end portion 129 of the gate line 121 or the end portion 179 of the data line 171 with an external device such as a driving integrated circuit (“IC”), and protect them.

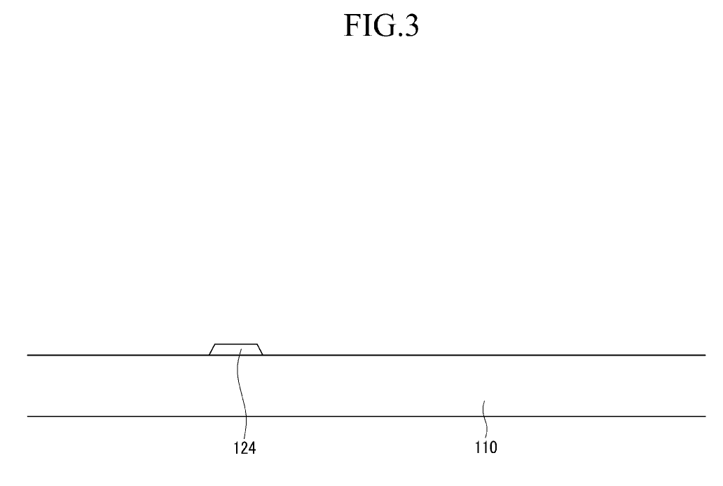

A method for manufacturing the TFT array panel as shown in FIGS. 1 and 2 will now be described with reference to FIGS. 3 to 10 together with FIGS. 1 and 2.

FIGS. 3 to 10 are sequential sectional views showing a method for manufacturing the TFT array panel in FIGS. 1 and 2.

First, with reference to FIG. 3, the gate line 121 including the gate electrode 124 is formed on a surface of the substrate 110.

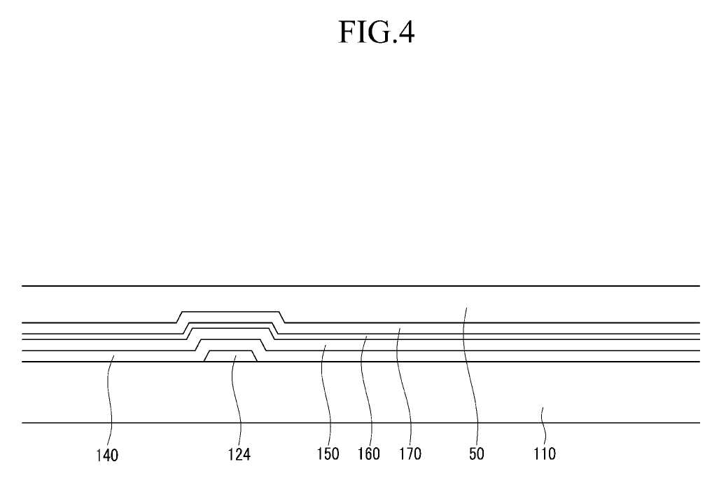

With reference to FIG. 4, the gate insulating layer 140 formed on the surface of the substrate 110 having the gate line 121 and gate electrode 124, an intrinsic amorphous silicon layer 150 formed on a surface of the gate insulating layer 140 opposite the substrate 110, and a doped amorphous silicon layer 160 formed on a surface of the intrinsic amorphous silicon layer 150 opposite gate insulating layer 140 are each sequentially stacked by sequential formation using plasma enhanced chemical vapor deposition (“PECVD”).

Subsequently, a data conductive layer 170 is formed on a surface of the doped amorphous silicon layer 160 by a suitable method such as, for example, sputtering.

Next, a photoresist film 50 is coated on a surface of the data conductive layer 170 according to a spin coating method. The photoresist film is made using a photoresist resin composition including an alkali soluble resin, a photoresist compound, and a solvent according to an embodiment, and as described above.

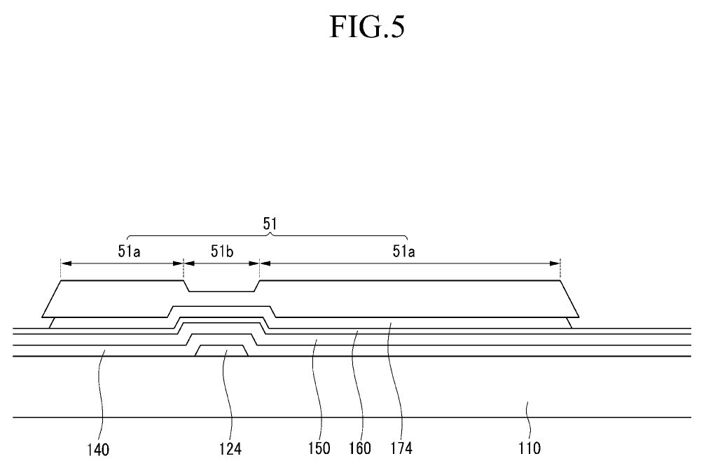

With reference to FIG. 5, the photoresist film 50 is exposed and developed to form a photoresist pattern 51 including first portions 51a and a second portion 51b thinner than the first portions 51a. Thereafter, the photoresist pattern 51 is hard-baked at about 120° C. to about 140° C. for about 90 seconds The photoresist pattern 51 according to an exemplary embodiment has sufficient heat resistance at a temperatures of about 120° C. to about 140° C. such that it is not thermally deformed during hard baking.

The first portions 51a of the photoresist pattern 51 are positioned at regions where a data pattern such as the data line 171 including the source electrode 173 and the drain electrode 175 is to be formed, and the second portion 51b is positioned at a region where a channel of the TFT is to be formed between the source electrode 173 and the drain electrode 175.

In this case, the thickness ratio of the first portions 51a and the second portion 51b of the photoresist pattern 51 may vary depending on etching process conditions (to be described hereinbelow), and in an embodiment, the thickness of the second portion 51b is about one half (0.5×) the thickness of the first portions 51a.

Various methods for forming the photoresist pattern may be employed such that portions of the patterned photoresist film have different thicknesses according to their positions, which may be accomplished by for example, exposure of the photoresist film through an exposure mask that includes a transparent area, a light blocking area, and a semi-transparent area. The semi-transparent area may include, for example, a slit pattern, a lattice pattern, or a thin film having a median transmittance or having a median thickness. When a slit pattern is used, in an embodiment the width of the slits and/or the space between the slits is smaller than resolution of a light exposure source typically used for photolithography.

Subsequently, the data conductive layer 170 is etched by using the photoresist pattern 51 as a mask to form the data pattern 174.

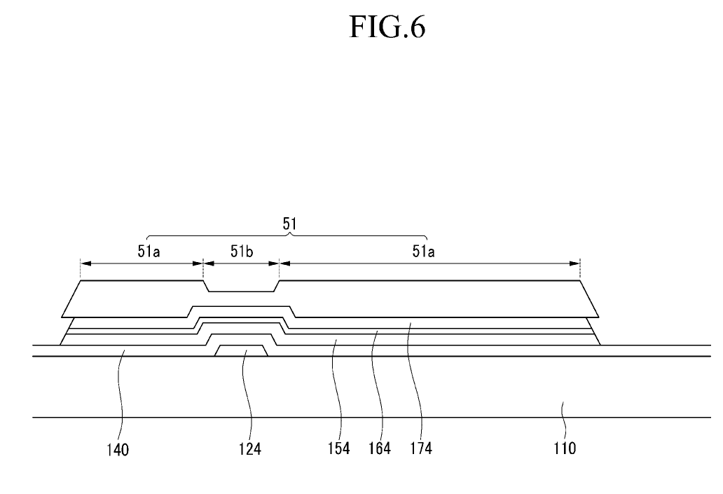

As shown in FIG. 6, the doped amorphous silicon layer 160 and the intrinsic amorphous silicon layer 150 are both etched by using the photoresist pattern 51 and the data pattern 174 as a mask to form the semiconductor stripe 151 including the projection 154 and the ohmic contact layer 164.

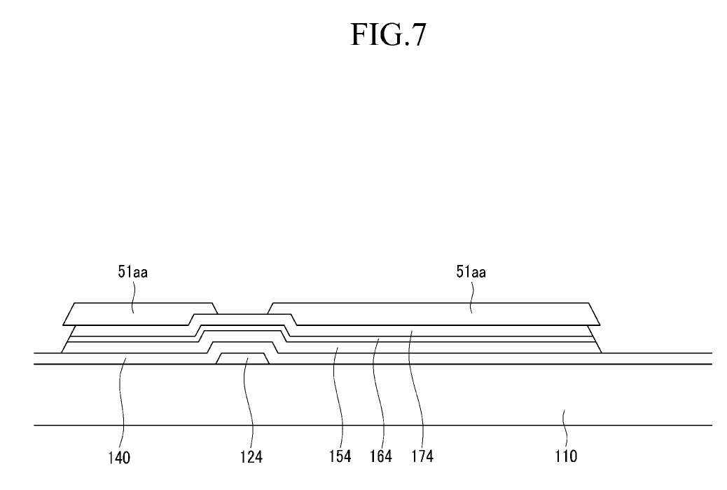

Thereafter, as shown in FIG. 7, the second portion 51b of the photoresist pattern 51 is removed by using an etch-back process. In this case, the first portions 51a of the photoresist pattern 51 are also removed to some extent, leaving thinner photoresist patterns 51aa.

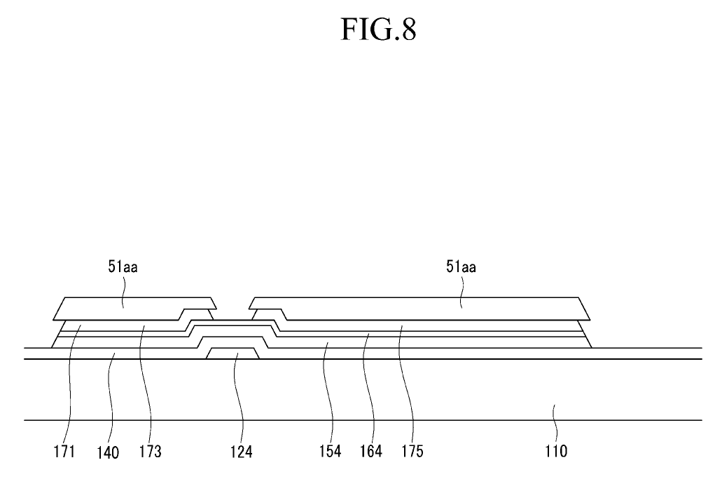

With reference to FIG. 8, the data pattern 174 is etched to separate the source electrode 173 and the drain electrode 175, and the ohmic contact layer 154 is exposed by using the photoresist patterns 51aa as masks.

In this case, dry etching or wet etching may be performed.

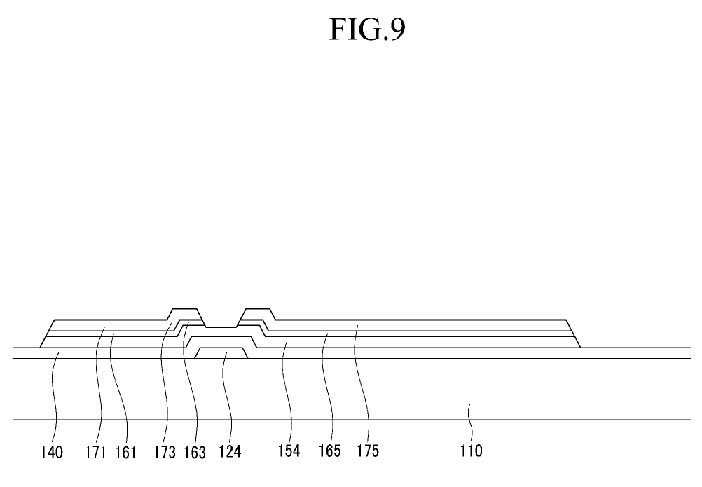

With reference to FIG. 9, the photoresist patterns 51aa are removed and the exposed portion of the ohmic contact layer 164 is removed through back channel etching (BCH) to separate ohmic contact stripes 161 and ohmic contact islands 165.

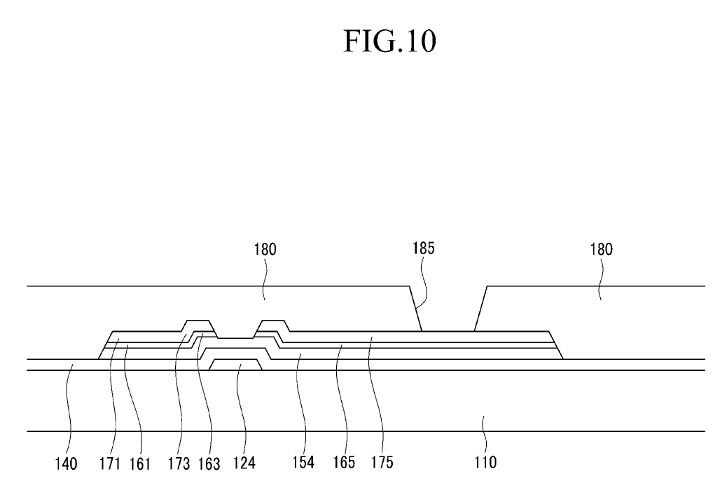

With reference to FIG. 10, the passivation layer 180 is formed on the entire surface of the substrate including the data line 171 and the drain electrode 175.

Subsequently, the plurality of contact holes 181, 182, and 185 are formed at the passivation layer 180.

With reference back to FIGS. 1 and 2, the pixel electrode 191 and the contact assistants 81 and 82 are formed on a surface of the passivation layer 180.

The photoresist resin according to the exemplary embodiment of the present invention can accomplish pattern uniformity and improve productivity by satisfying the heat resistance, sensitivity, contrast, and film thickness uniformity.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A photoresist resin composition comprising an alkali soluble resin, a photoresist compound, and a solvent, wherein the alkali soluble resin comprises a first polymer resin represented by the following Chemical Formula 1, 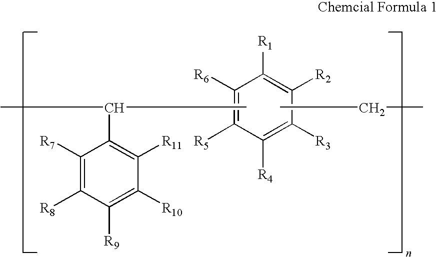
wherein, of R₁, R₂, R₃, R₄, R₅ and R₆, at least one is a hydroxyl group, at least two are methyl groups and any remaining groups are hydrogen, and of R₇, R₈, R₉, R₁₀ and R₁₁, at least one is a hydroxyl group, at least two are methyl groups and any remaining groups are hydrogen.

2. The photoresist resin composition of claim 1, wherein the alkali soluble resin further comprises a second polymer resin selected from the group consisting of a novolak resin, an acrylic resin, and a combination thereof.

3. The photoresist resin composition of claim 2, wherein the first polymer resin is included in an amount of about 1 wt % to about 50 wt % based on the total weight of the alkali soluble resin.

4. The photoresist resin composition of claim 3, wherein the first polymer resin is formed from a phenol monomer and an aldehyde compound, and the aldehyde compound is a salicylaldehyde compound.

5. The photoresist resin composition of claim 1, wherein the photoresist compound is a diazonaphthoquinone compound.

6. The photoresist resin composition of claim 1, wherein the photoresist resin composition comprises about 5 wt % to about 30 wt % of the alkali soluble resin, about 2 wt % to about 10 wt % of the photoresist compound, and the remaining amount of a solvent, based on the total weight of the photoresist resin composition.

7. A method for forming a pattern, comprising:
forming a thin film on a substrate;
forming a photoresist film by coating a photoresist resin composition comprising an alkali soluble resin comprising a first polymer resin represented by the following Chemical Formula 1, a photoresist compound, and a solvent on the thin film, 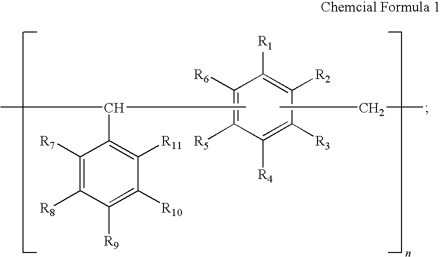
exposing and developing the photoresist film to form a photoresist pattern; and
etching the thin film through the photoresist pattern,
wherein, of R₁, R₂, R₃, R₄, R₅ and R₆, at least one is a hydroxyl group, at least two are methyl groups and any remaining groups are hydrogen, and of R₇, R₈, R₉, R₁₀ and R₁₁, at least one is a hydroxyl group, at least two are methyl groups and any remaining groups are hydrogen.

8. The method of claim 7, wherein the alkali soluble resin further comprises a second polymer resin selected from the group consisting of a novolak resin, an acrylic resin, and a combination thereof.

9. The method of claim 8, wherein the first polymer resin is included in an amount of about 5 wt % to about 50 wt % based on the total weight of the alkali soluble resin.

10. A method for manufacturing a display panel, comprising:
forming a gate line;
sequentially forming a gate insulating layer, a semiconductor layer, and a data conductive layer on the gate line;
forming a photoresist film by coating a photoresist resin composition comprising an alkali soluble resin comprising a first polymer resin represented by the following Chemical Formula 1, a photoresist compound, and a solvent on the data conductive layer 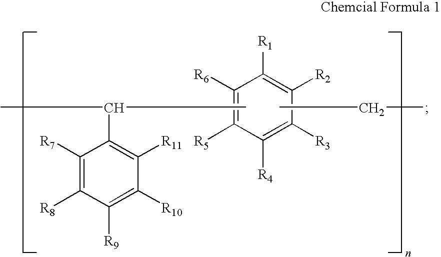
exposing and developing the photoresist film to form a photoresist pattern;
etching the data conductive layer and the semiconductor layer through the photoresist pattern;
removing a portion of the photoresist pattern to leave a portion of the photoresist pattern; and
etching the data conductive layer through the remaining photoresist pattern to form source and drain electrodes,
wherein, of R₁, R₂, R₃, R₄, R₅ and R₆, at least one is a hydroxyl group, at least two are methyl groups and any remaining groups are hydrogen, and of R₇, R₈, R₉, R₁₀ and R₁₁, at least one is a hydroxyl group, at least two are methyl groups and any remaining groups are hydrogen.

11. The method of claim 10, wherein the alkali soluble resin further comprises a second polymer resin selected from the group consisting of a novolak resin, an acrylic resin, and a combination thereof.

12. The method of claim 11, wherein the first polymer resin is included in an amount of about 5 wt % to about 50 wt % based on the total weight of the alkali soluble resin.

13. The method of claim 10, wherein the forming of the photoresist pattern comprises irradiating the photoresist film with a light exposure energy of about 20 mJ/cm² to about 40 mJ/cm² to the photoresist film.

14. The method of claim 10, wherein forming of the photoresist pattern comprises performing a thermal treatment, and the thermal treatment is performed at about 120° C. to about 140° C.

15. The method of claim 10, wherein the photoresist pattern comprises a first portion and a second portion thinner than the first portion, and wherein when the photoresist pattern is partially removed, the second portion is removed.

16. The method of claim 15, wherein the second portion is positioned between the source and drain electrodes.
